(19) United States
(12) Patent Application Publication
(10) Pub. No.: US 2026/0319882 A1
(43) Pub. Date: Oct. 15, 2026

(54) INTEGRATED CIRCUIT PROVIDING BUILT-IN SELF-REPAIR AND METHOD THEREFOR

(71) Applicant: Samsung Electronics Co., Ltd., Suwon-si (KR)

(72) Inventors: Yeonho Jung, Suwon-si (KR); Jaeseok Park, Suwon-si (KR); Seohyun Kang, Suwon-si (KR); Dahyun Kang, Suwon-si (KR)

(21) Appl. No.: 19/535,727

(22) Filed: Feb. 10, 2026

(30) Foreign Application Priority Data
Apr. 15, 2025 (KR) 10-2025-0049013

(51) Int. Cl. G06F 11/07; G01R 31/3177

(52) U.S. Cl. CPC G06F 11/0793; G01R 31/3177; G06F 11/0721

(57) ABSTRACT

The present disclosure relates to an integrated circuit including hardware resources. An example integrated circuit includes at least one first flipflop configured to latch scan data output from the integrated circuit in a first mode and to latch repair data in a second mode, and a control circuit configured to repair a defective resource among the hardware resources based on the repair data latched by the at least one first flipflop in the second mode.

### CROSS-REFERENCE TO RELATED APPLICATION

This application claims the benefit of Korean Patent Application No. 10-2025-0049013, filed on Apr. 15, 2025, in the Korean Intellectual Property Office, the disclosure of which is incorporated herein by reference in its entirety.

### BACKGROUND

Integrated circuits may exhibit errors caused by various factors. For example, each of the wafers, as well as the chips in a wafer may exhibit different characteristics resulting from a semiconductor manufacturing process. As a result, integrated circuits that fail to provide the designed function and/or performances may be produced. If all integrated circuits that fail testing are discarded, the overall yield of integrated circuits in the semiconductor manufacturing process may be reduced significantly.

### SUMMARY

The present disclosure relates to an integrated circuit providing built-in self-repair and a method therefor.

In some implementations, an integrated circuit comprising a plurality of hardware resources includes at least one first flipflop configured to latch scan data in a first mode and to latch repair data in a second mode, the scan data being output from the integrated circuit, and a control circuit configured to repair a defective resource among the plurality of hardware resources based on the repair data latched by the at least one first flipflop in the second mode.

In some implementations, a method performed by an integrated circuit comprising a plurality of hardware resources includes latching scan data by at least one first flipflop in a first mode, the scan data being output from the integrated circuit, latching repair data by the at least one first flipflop in a second mode, and repairing a defective resource, among the hardware resources, based on the repair data latched in the at least one first flipflop in the second mode.

In some implementations, a method performed by at least one processor for an integrated circuit providing built-in self-repair includes obtaining input data defining a plurality of hardware resources included in the integrated circuit and generating output data defining the integrated circuit based on the input data. The generating of the output data includes adding information defining at least one first flipflop configured to latch scan data in a first mode and to latch repair data in a second mode to the input data, adding information defining a repair circuit configured to provide the repair data to the at least one first flipflop in the second mode to the input data, and adding information defining a control circuit configured to repair a defective resource among the plurality of hardware resources based on the repair data latched by the at least one first flipflop to the input data.

### BRIEF DESCRIPTION OF THE DRAWINGS

These and/or other aspects, features, and advantages of the present disclosure will become apparent and more readily appreciated from the following description of example implementations, taken in conjunction with the accompanying drawings.

FIG. 1 illustrates an example of an integrated circuit.

FIG. 2 illustrates an example of a flipflop.

FIGS. 3A and 3B illustrate examples of function blocks

FIG. 4 illustrates an example of an integrated circuit.

FIG. 5 illustrates an example of a control circuit.

FIG. 6 illustrates an example of an integrated circuit.

FIGS. 7A, 7B, and 7C illustrate examples of multiplexing circuits.

FIG. 8 illustrates an example of a system.

FIG. 9 is a flowchart illustrating an example of a method of built-in self-repair.

FIG. 10 is a flowchart illustrating an example of a method of built-in self-repair.

FIG. 11 is a flowchart illustrating an example of a method of built-in self-repair.

FIG. 12 is a flowchart illustrating an example of a method of manufacturing an integrated circuit.

FIG. 13 is a flowchart illustrating an example of a method of built-in self-repair.

FIG. 14 is a block diagram illustrating an example of a system-on-chip (SoC).

FIG. 15 is a block diagram illustrating an example of a computing system including a memory for storing a program.

### DETAILED DESCRIPTION

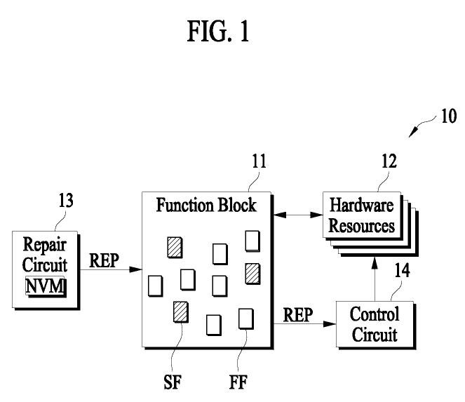

FIG. 1 illustrates an example of an integrated circuit 10. The integrated circuit 10 may be any device manufactured using a semiconductor manufacturing process. For example, the integrated circuit 10 may be included in a chip diced from a wafer and be packaged alone or with at least one other chip. As illustrated in FIG. 1, the integrated circuit 10 may include a function block 11, hardware resources 12, a repair circuit 13, and a control circuit 14. Similar to the control circuit 14, a block illustrated herein may have any structure designed to perform a given function. For example, a block may include at least one processor for executing software, such as a central processing unit (CPU), graphic processing unit (GPU), and neural processing unit (NPU), a hardware intellectual property (hardware IP) designed to perform a fixed function such as a hardware accelerator, or a reconfigurable component such as a field programmable gate array (FPGA).

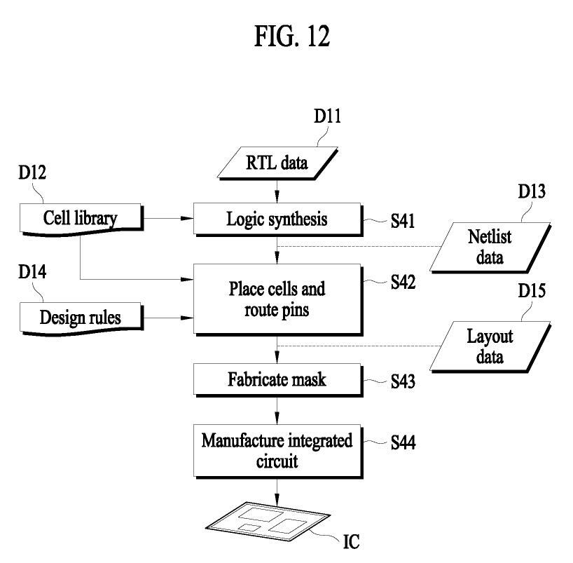

The function block 11 may be designed to perform a function required by the integrated circuit 10. For example, the function block 11 may be designed to process a digital signal, and may include various types of logic circuits including a combinational logic and/or sequential logic. In some implementations, the function block 11 may be implemented through logic synthesis, as will be described later with reference to FIG. 12. As illustrated in FIG. 1, the function block 11 may include scan flipflops SF and function flipflops FF as a sequential logic. Herein, the scan flipflops SF may be referred to as first flipflops, while the function flipflops FF may be referred to as second flipflops.

The function block 11 may perform its function using the hardware resources 12. In some implementations, the hardware resources 12 may include calculation blocks, and the function block 11 may perform calculations using the calculation blocks. In some implementations, the hardware resources 12 may include memory cells, and the function block 11 may perform its function by writing data to the memory cells or reading data from the memory cells.

Each of a plurality of wafers may exhibit different characteristics resulting from the semiconductor manufacturing process for manufacturing the integrated circuit 10. A plurality of chips in the wafer may also exhibit different characteristics, and the hardware resources 12 included in the integrated circuit may exhibit different characteristics as well. Accordingly, the hardware resources 12 may include a defective resource, that is, a resource that does not provide a designed function and/or performance. When a defective resource is used by the function block 11, the integrated circuit 10 may exhibit an error and may be tested to detect the defective resource. When all integrated circuits that did not pass the test are discarded, the yield of the integrated circuit 10 in the semiconductor manufacturing process may be reduced significantly. The integrated circuit 10 may provide built-in self-repair to repair a defective resource, as described below. The hardware resources 12 may include a redundancy resource, and the built-in self-repair may be carried out by replacing the defective resource with the redundancy resource. Reliability and yield of the integrated circuit 10 may be enhanced by built-in self-repair.

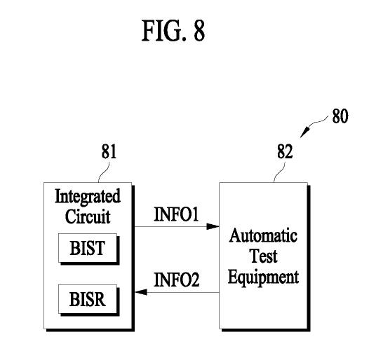

The repair circuit 13 may provide repair data REP to the function block 11. The repair data REP may refer to data required to repair a defective resource included in the hardware resources 12. For example, the repair data REP may include information on a defective resource and/or a redundancy resource among the hardware resources. As illustrated in FIG. 1, the repair circuit 13 may include a non-volatile memory NVM and the non-volatile memory NVM may store the repair data REP. Accordingly, the repair data REP may not be lost even when the power supplied to the integrated circuit 10 is cut. In some implementations, the non-volatile memory NVM may include a one-time programmable memory (OTP memory) such as eFuse. As will be described below with reference to FIG. 8, the repair data REP may be written to the non-volatile memory NVM while the integrated circuit 10 is being tested.

The function block 11 may be set to a scan mode or a normal mode. For example, the function block 11 may be set to the scan mode or the normal mode based on a signal received from the outside of the integrated circuit 10. Herein, the scan mode may be referred to as a first mode, while the normal mode may be referred to as a second mode. In scan mode, the integrated circuit 10 may output the scan data, that is, data stored in sequential logics of the function block 11, at a given time (e.g., a specific clock cycle), to the outside through a scan chain to check status of the function block 11 or to debug the function block 11. The scan flipflops SF and function flipflops FF may be included in the scan chain and may latch scan data in the scan mode.

The function block 11 may perform a designed function in the normal mode. The function flipflops FF in normal mode may latch function data, that is, data generated as the function block 11 performs the designed function. The function block 11 may operate based on data latched in the function flipflops FF, and the data generated may be latched in the function flipflops FF. In normal mode, the scan flipflops SF may latch the repair data REP. For example, the scan flipflops SF may latch repair data REP provided by the repair circuit 13 and provide the latched repair data REP to the control circuit 14. Unlike function flipflops FF that are used for the operation of the function block 11 in the normal mode, the scan flipflops SF may latch repair data REP and hold repair data REP to be provided to the control circuit 14.

The control circuit 14 may repair a defective resource among the hardware resources 12 based on the repair data REP provided by the function block 11. For example, the control circuit 14 may receive repair data REP from the scan flipflops SF of the function block 11 in the normal mode. The control circuit 14 may identify a defective resource and/or a redundancy resource among the hardware resources based on the repair data REP. The control circuit 14 may switch function block 11's access to the defective resource to an access to the redundancy resource. The repair circuit 13 and the control circuit 14 may be referred to as a built-in self-repair circuit in general.

Scan flipflops SF may be inserted to observe operation of the function block 11 in the scan mode. The scan flipflops SF may be inserted regardless the function of the function block 11 to ease observation of status of the function block 11 or to debug the function block 11, and observability of the function block 11 may be enhanced by the scan flipflops SF. Accordingly, while the scan flipflops SF may be used for latching scan data in the scan mode, the scan flipflops SF may not be used for the operation of the function block 11 in the normal mode. In normal mode, the control circuit 14 may require consistent repair data REP, and latches to hold the repair data REP in the normal mode may be required. As described above, the scan flipflops SF inserted to observe the operation of the function block 11 may be used to hold the repair data REP in the normal mode, thereby eliminating the need for additional latches for holding the repair data REP. As a result, the built-in self-repair in the integrated circuit 10 may be implemented with a reduced cost, and efficiency of the integrated circuit 10 may be improved.

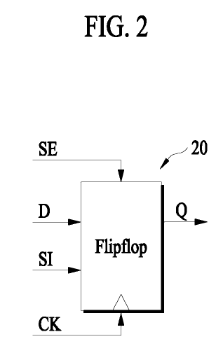

FIG. 2 illustrates an example of a flipflop 20. For example, the flipflop 20 of FIG. 2 may be an example of the scan flipflops SF and function flipflops FF of FIG. 1. The scan flipflops SF and function flipflops FF of FIG. 1 are not limited to the flipflop 20 of FIG. 2. Hereinafter, FIG. 2 will be described with reference to FIG. 1.

Referring to FIG. 2, the flipflop 20 may include data input D, scan input SI, scan enable input SE, clock input CK, and data output Q. When the scan enable input SE is deactivated, that is, when the integrated circuit 10 is in the normal mode, the flipflop 20 may latch the data input D based on the clock input CK, and output the latched data input D as the data output Q. When the scan enable input SE is activated, that is, when the integrated circuit 10 is in the scan mode, the flipflop 20 may latch the scan input SI based on the clock input CK, and output the latched scan input SI as the data output Q.

In some implementations, each of the scan flipflops SF and function flipflops FF may receive data output of a previous flipflop in the scan chain as the scan input SI. In some implementations, each of the scan flipflops SF may receive one bit of the repair data REP as the data input D, and each of the function flipflops FF may receive an output bit of a combination logic of the function block 11 as the data input D.

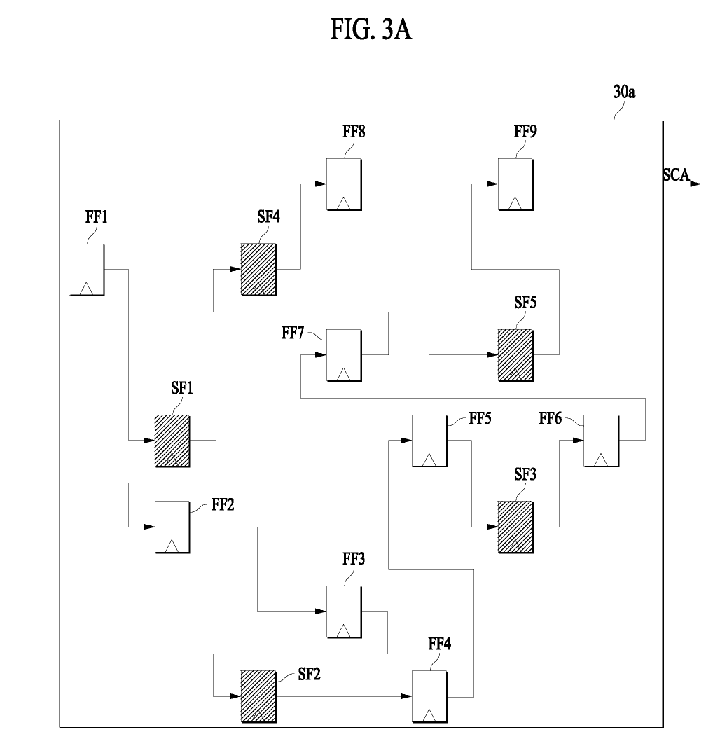

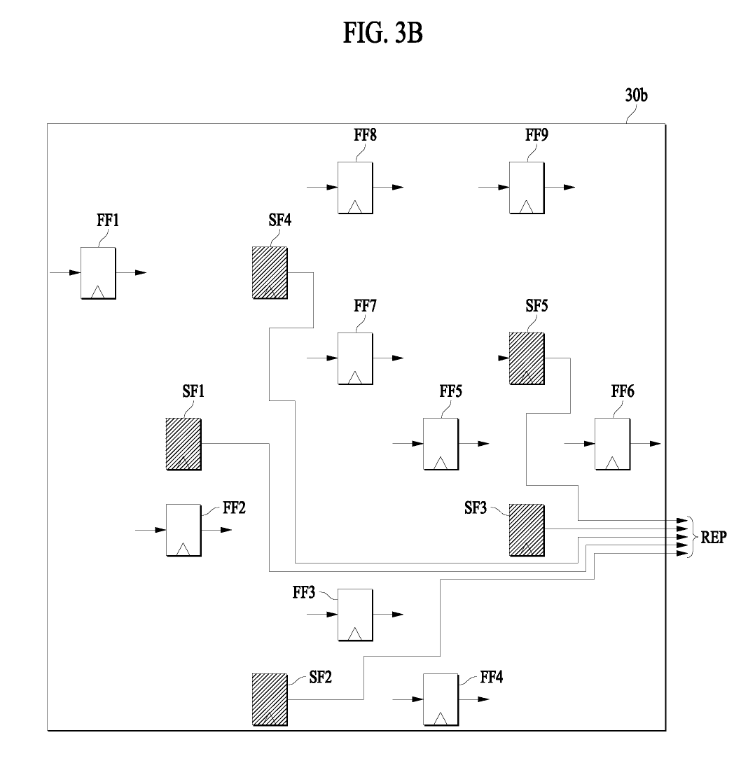

FIGS. 3A and 3B illustrate examples of function blocks. For example, FIG. 3A illustrates a function block 30a in the scan mode, while FIG. 3B illustrates a function block 30b in the normal mode. As illustrated in FIGS. 3A and 3B, the function blocks 30a and 30b may include first to fifth scan flipflops SF1 to SF5 and first to ninth function flipflops FF1 to FF9.

Referring to FIG. 3A, the function block 30a may be set to the scan mode, and scan data SCA may be transmitted through the scan chain. As illustrated in FIG. 3A, the first to fifth scan flipflops SF1 to SF5 and first to ninth function flipflops FF1 to FF9 may be connected to one another in a chain. The scan data SCA may be output from the function block 30a as a final output. In some implementations, unlike what is illustrated in FIG. 3A, scan flipflops and function flipflops may each be included in different scan chains. For example, the scan flipflops may be included in a first scan chain and the function flipflops may be included in a second scan chain.

Referring to FIG. 3B, the function block 30b may be set to the normal mode, and the first to fifth scan flipflops SF1 to SF5 and first to ninth function flipflops FF1 to FF9 may perform their own functions. As illustrated in FIG. 3B, each of the first to fifth scan flipflops SF1 to SF5 may latch and output bits of the repair data REP. Additionally, the first to ninth function flipflops FF1 to FF9 may latch bits required to perform a designed function of the function block 30b. The built-in self-repair may be implemented at reduced cost as the first to fifth scan flipflops SF1 to SF5 are used to latch the repair data REP in the normal mode, as described above with reference to FIG. 1.

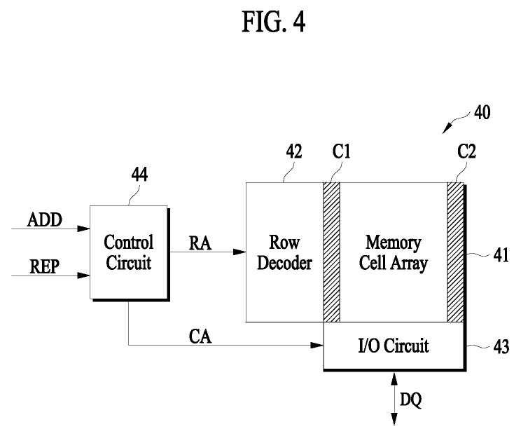

FIG. 4 illustrates an example of an integrated circuit 40. For example, FIG. 4 illustrates an integrated circuit 40 including memory cells as an example of the hardware resources 12 of FIG. 1. As illustrated in FIG. 4, the integrated circuit 40 may include a memory cell array 41, a row decoder 42, an input/output circuit 43, and a control circuit 44.

The memory cell array 41 may include a plurality of memory cells. A memory cell may store at least one bit, and may be simply referred to as a cell herein. In some implementations, the memory cell may be a volatile memory cell, such as a dynamic random-access memory (DRAM) cell or a static random-access memory (SRAM) cell, or a non-volatile memory cell, such as a flash memory cell or a resistive random-access memory (RRAM) cell.

The memory cell array 41 may include both normal cells and defective cells resulting from a semiconductor manufacturing process. The memory cell array 41 may include a redundancy cell to repair a defective cell. For example, as illustrated in FIG. 4, the memory cell array 41 may include at least one first redundancy column C1 and at least one second redundancy column C2. In some implementations, unlike what is illustrated in FIG. 4, the memory cell array 41 may include at least one redundancy row. Hereinafter, the memory cell array 41 including a redundancy column will be described mainly, however, example implementations of the present disclosure are not limited thereto.

The row decoder 42 may be connected to the plurality of memory cells through a plurality of word lines, and receive a row address RA from the control circuit 44. The row decoder 42 may select one of the plurality of word lines based on the row address RA and activate the selected word line. Among the plurality of memory cells, memory cells connected to the activated word line may be selected, and data may be written to the selected memory cells or read from the selected memory cells.

The input/output circuit 43 may be connected to the plurality of memory cells through a plurality of bit lines, and receive a column address CA from the control circuit 44. The input/output circuit 43 may include a column decoder, and the column decoder may select one or more columns from the plurality of columns of the memory cell array 41 based on the column address CA. The input/output circuit 43 may write data by applying a signal (e.g., a voltage and/or current) to bit lines corresponding to the selected columns based on a data signal DQ. In addition, the input/output circuit 43 may read data by detecting a signal received (e.g., a voltage and/or current) from the selected columns.

The control circuit 44 may receive an address ADD and repair data REP. As described above with reference to the drawings, the repair data REP may be received from the scan flipflops of the function block in the normal mode. The control circuit 44 may extract the row address RA and column address CA from the address ADD. In some implementations, the control circuit 44 may identify an address of a redundancy column based on the repair data REP. When the address ADD requests for an access to a defective cell, the control circuit 44 may generate and provide a column address CA to the input/output circuit 43 to have access to the redundancy column. Accordingly, the access to the defective cell may be switched to the access to the redundancy cell, and the self-repair may be completed.

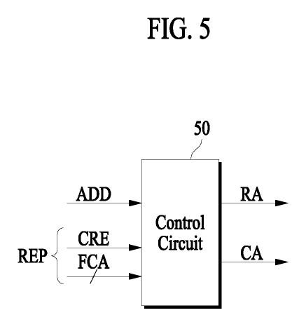

FIG. 5 illustrates an example of a control circuit 50. For example, FIG. 5 illustrates a control circuit 50 that switches an access to a defective cell to an access to a redundancy cell in a memory cell array. As described above with reference to FIG. 4, the control circuit 50 may receive an address ADD and repair data REP and generate a row address RA and a column address CA. A description of FIG. 5 overlapping with that of FIG. 4 will be omitted.

Referring to FIG. 5, the repair data REP may include a cell repair enable CRE and a fail cell address FCA. The cell repair enable CRE may indicate whether the cell is required to be repaired, and the fail cell address FCA may indicate an address of a redundancy cell (or a redundancy column). While the fail cell address FCA may indicate an address of a redundancy cell when the cell repair enable CRE has an activated value, when the cell repair enable CRE has a deactivated value, the fail cell address FCA corresponding to the cell repair enable CRE may be irrelevant to the address of the redundancy cell. In some implementations, the fail cell address FCA may be a multi-bit.

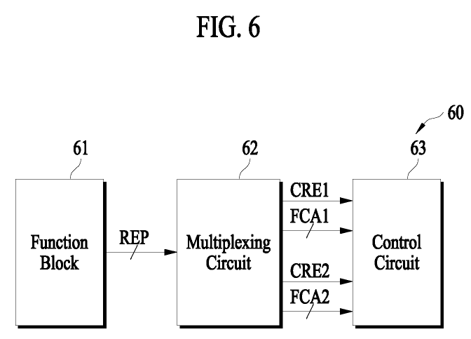

The control circuit 50 may generate a column address CA based on the fail cell address FCA when the cell repair enable CRE has an activated value. In some implementations, as will be described below with reference to the drawings such as FIG. 6, the cell repair enable CRE and the fail cell address FCA may be generated by processing the repair data REP stored in the scan flipflops. Herein, the cell repair enable CRE may be referred to as first data, and the fail cell address FCA may be referred to as second data.

FIG. 6 illustrates an example of an integrated circuit 60. For example, FIG. 6 illustrates an integrated circuit 60 including a control circuit 63 that switches an access to a defective cell to an access to a redundancy cell in a memory cell array. As illustrated in FIG. 6, the integrated circuit 60 may include a function block 61, a multiplexing circuit 62, and a control circuit 63. A description of FIG. 6 overlapping with the above-descriptions provided with reference to the drawings will be omitted.

The control circuit 63 may receive a first cell repair enable CRE1, a first fail cell address FCA1, a second cell repair enable CRE2, and a second fail cell address FCA2. The control circuit 63 may selectively use the first fail cell address FCA1 based on the first cell repair enable CRE1, and may selectively use the second fail cell address FCA2 based on the second cell repair enable CRE2.

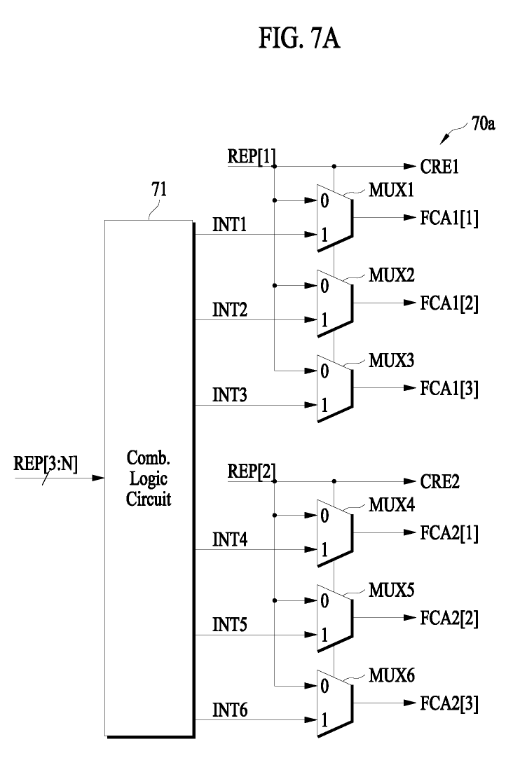

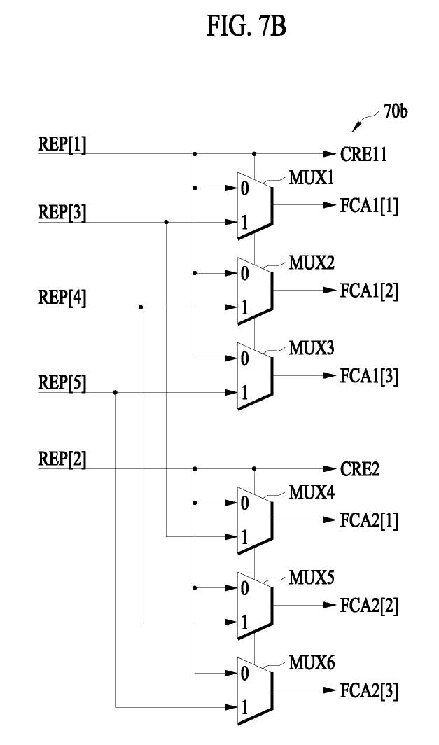

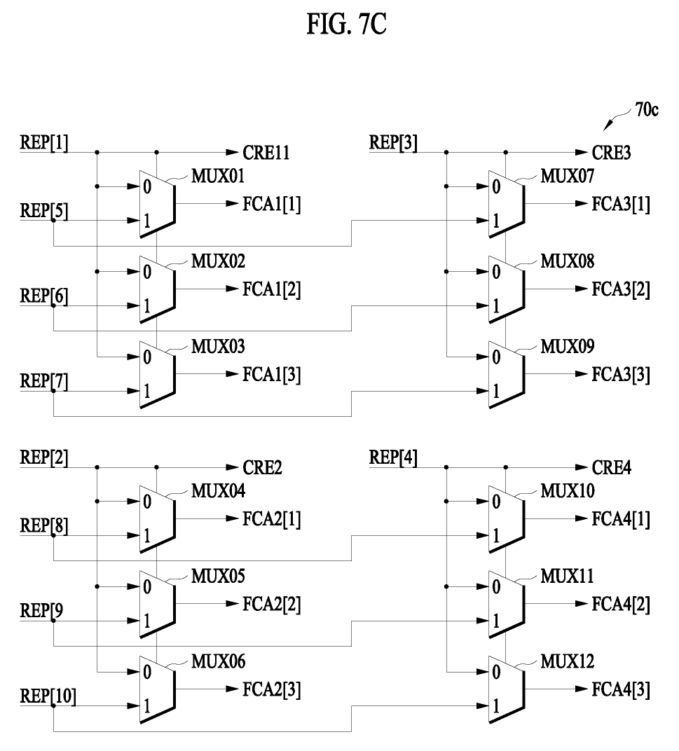

In some implementations, at least one of scan flipflops included in the function block 61 may be shared to repair defective cells among memory cells, that is, the hardware resources. That is, the number of bits of the first cell repair enable CRE1, the first fail cell address FCA1, the second cell repair enable CRE2, and the second fail cell address FCA2 may be greater than the number of bits of the repair data REP provided by the function block 61. For this, the multiplexing circuit 62 may generate the first cell repair enable CRE1, the first fail cell address FCA1, the second cell repair enable CRE2, and the second fail cell address FCA2 from the repair data REP provided by the function block 61. In some implementations, as will be described blow with reference to FIG. 7C, the multiplexing circuit 62 may generate an additional pair of cell repair enable and fail cell address. Examples of the multiplexing circuit 62 will be described below with reference to FIGS. 7A through 7C.

FIGS. 7A, 7B, and 7C illustrate examples of multiplexing circuits. As described above with reference to FIG. 6, multiplexing circuits 70a, 70b, and 70c may generate a cell repair enable and a fail cell address to be provided to the control circuit from the repair data REP provided by the function block. The multiplexing circuit 62 of FIG. 6 is not limited to the examples of FIGS. 7A through 7C. Hereinafter, redundant details in the descriptions of FIGS. 7A through 7C will be omitted.

Referring to FIG. 7A, the multiplexing circuit 70a may generate a first cell repair enable CRE1, a first fail cell address FCA1[1:3], a second cell repair enable CRE2, and a second fail cell address FCA2[1:3] from N-bit repair data REP[1:N]. The N may be a positive integer greater than 1, and may be less than 8, which is the total number of bits for the first cell repair enable CRE1, the first fail cell address FCA1 [1:3], the second cell repair enable CRE2, and the second fail cell address FCA2 [1:3]. As illustrated in FIG. 7A, the multiplexing circuit 70a may include a combinational logic circuit 71 and first to sixth multiplexers MUX1 to MUX6.

The combinational logic circuit 71 may generate first to sixth internal signals INT1 to INT6 from a portion REP [3:N] of the repair data REP [1:N]. In some implementations, the combinational logic circuit 71 may generate the first to sixth internal signals INT1 to INT6 from the portion REP[3:N] of the repair data REP[1:3] based on the trend of a semiconductor manufacturing process. For example, defective cells may exhibit a correlation resulting from a semiconductor manufacturing process, and the combinational logic circuit 71 may generate the first to sixth internal signals INT1 to INT6 from the portion REP [3:N] of the repair data REP [1:N] based on the analyzed correlation between the defective cells. In some implementations, at least two of the first to sixth internal signals INT1 to INT6 may correspond to the same signal.

When a first bit REP[1] of the repair data corresponding to the first cell repair enable CRE1 is activated, that is, when repair of a fail cell is indicated, the first to third multiplexers MUX1 to MUX3 may output the first to third internal signals INT1 to INT3 as the first fail cell address FCA1[1:3]. In addition, the first to third multiplexers MUX1 to MUX3 may output the first bit REP[1]of the repair data as the first fail cell address FCA1[1:3] when the first bit REP[1] of the repair data is deactivated. Similarly, when a second bit REP[2] of the repair data corresponding to the second cell repair enable CRE2 is activated, that is, when repair of a fail cell is indicated, the fourth to sixth multiplexers MUX4 to MUX6 may output fourth to sixth internal signals INT4 to INT6 as the second fail cell address FCA2[1:3]. In addition, the fourth to sixth multiplexers MUX4 to MUX6 may output the second bit REP[2] of the repair data as the second fail cell address FCA2[1:3] when the second bit REP[2] of the repair data is deactivated.

Referring to FIG. 7B, the multiplexing circuit 70b may generate a first cell repair enable CRE1, a first fail cell address FCA1[1:3], a second cell repair enable CRE2, and a second fail cell address FCA2[1:3] from 5-bit repair data REP[1:5]. As illustrated in FIG. 7B, the multiplexing circuit 70b may include first to sixth multiplexers MUX1 to MUX6.

When a first bit REP[1] of repair data corresponding to the first cell repair enable CRE1 is activated, that is, when repair of a fail cell is indicated, the first to third multiplexers MUX1 to MUX3 may output the third to fifth bit REP[3:5] of repair data as the first fail cell address FCA1[1:3]. In addition, the first to third multiplexers MUX1 to MUX3 may output the first bit REP[1]of the repair data as the first fail cell address FCA1[1:3] when the first bit REP[1] of the repair data is deactivated. Similarly, when a second bit REP[2] of repair data corresponding to the second cell repair enable CRE2 is activated, that is, when repair of a fail cell is indicated, the fourth to sixth multiplexers MUX4 to MUX6 may output the third to fifth bit REP[3:5]of the repair data as the second fail cell address FCA2[1:3]. In addition, the fourth to sixth multiplexers MUX4 to MUX6 may output the second bit REP[2]of the repair data as the second fail cell address FCA2[1:3] when the second bit REP[2]of the repair data is deactivated.

Referring to FIG. 7C, the multiplexing circuit 70c may generate first to fourth cell repair enables CRE1 to CRE4, and first to fourth fail cell addresses FCA1[1:3] to FCA4[1:3] from 10-bit repair data REP[1:10]. As illustrated in FIG. 7C, the multiplexing circuit 70c may include first to twelfth multiplexers MUX1 to MUX12.

When a first bit REP[1]of the repair data corresponding to the first cell repair enable CRE1 is activated, that is, when repair of a fail cell is indicated, the first to third multiplexers MUX1 to MUX3 may output the fifth to seventh bit REP[5:7] of repair data as the first fail cell address FCA1[1:3]. In addition, the first to third multiplexers MUX1 to MUX3 may output the first bit REP[1] of the repair data as the first fail cell address FCA1[1:3] when the first bit REP[1] of the repair data is deactivated. Similarly, when a second bit REP[2] of the repair data corresponding to the second cell repair enable CRE2 is activated, that is, when repair of a fail cell is indicated, the fourth to sixth multiplexers MUX4 to MUX6 may output the eighth to tenth bit REP[8:10] of the repair data as the second fail cell address FCA2[1:3]. In addition, the fourth to sixth multiplexers MUX4 to MUX6 may output the second bit REP[2] of the repair data as the second fail cell address FCA2[1:3] when the second bit REP[2] of the repair data is deactivated.

When a third bit REP[3] of repair data corresponding to the third cell repair enable CRE3 is activated, that is, when repair of a fail cell is indicated, the seventh to ninth multiplexers MUX7 to MUX9 may output the fifth to seventh bit REP[5:7] of the repair data as the third fail cell address FCA3[1:3]. In addition, the seventh to ninth multiplexers MUX7 to MUX9 may output the third bit REP[3] of the repair data as the third fail cell address FCA3[1:3] when the third bit REP[3] of the third repair data is deactivated. Similarly, when a fourth bit REP[4] of the repair data corresponding to the fourth cell repair enable CRE4 is activated, that is, when repair of a fail cell is indicated, the tenth to twelfth multiplexers MUX10 to MUX12 may output the eighth to tenth bit REP[8:10] of the repair data as the fourth fail cell address FCA4[1:3]. In addition, the tenth to twelfth multiplexers MUX10 to MUX12 may output the fourth bit REP[4] of the repair data as the fourth fail cell address FCA4[1:3] when the fourth bit REP[4] of the repair data is deactivated.

FIG. 8 illustrates an example of a system 80. For example, FIG. 8 illustrates a system 80 for testing an integrated circuit 81. In some implementations, the system 80 may be included in the process of manufacturing the integrated circuit 81. For example, the integrated circuit 81, after being manufactured through a semiconductor manufacturing process, may be tested by the system 80. A defective resource included in the integrated circuit 81 may be detected by the system 80, and information for repairing the defective resource may be generated, as described below. As illustrated in FIG. 8, the system 80 may include the integrated circuit 81 and an automatic test equipment 82. A description of FIG. 8 overlapping with a description provided above with reference to the drawings will be omitted.

Referring to FIG. 8, the automatic test equipment 82 may be connected to and communicate with the integrated circuit 81. For example, the integrated circuit 81 may include at least one port for communication with the automatic test equipment 82, and the automatic test equipment 82 may communicate with the integrated circuit 81 through the at least one port according to a pre-shared protocol.

The integrated circuit 81 may include a built-in self-test circuit BIST and a built-in self-repair circuit BISR. The built-in self-test circuit BIST may test hardware resources included in the integrated circuit 81 and provide first information INF01 including a result of the test to the automatic test equipment 82. For example, the built-in self-test circuit BIST may write predefined data to memory cells to test the memory cells, and may read data from the memory cells. The first information INF01 may include the data read from the memory cells and a result of a comparison conducted by the built-in self-test circuit BIST between the data written to the memory cells and the data read from the memory cells.

The automatic test equipment 82 may receive the first information INF01 from the integrated circuit 81, and may identify a defective resource included in the integrated circuit 81 based on the first information INF01. The automatic test equipment 82 may generate second information INF02 for repairing a defective resource based on the detected defective resource and provide the second information INF02 to the integrated circuit 81. For example, the automatic test equipment 82 may generate the second information INF02 including an address of a defective cell and/or an address of a redundancy cell for replacing the defective cell.

The built-in self-repair circuit BISR may receive the second information INF02 from the automatic test equipment 82. As described above with reference to FIG. 1, the built-in self-repair circuit BISR may include a non-volatile memory, and the second information INF02 may be stored in the non-volatile memory. For example, the built-in self-repair circuit BISR may include an OTP memory such as eFuse, and the automatic test equipment 82 may fuse the eFuse to store the second information INF02.

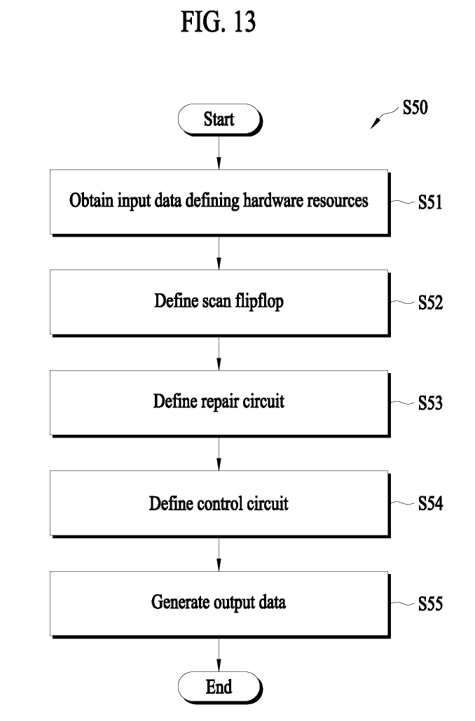

In some implementations, the built-in self-test circuit BIST may correspond to the function block described above with reference to the drawings. For example, the built-in self-test circuit BIST may include scan flipflops and function flipflops. The built-in self-test circuit BIST may test hardware resources, such as memory cells in the normal mode, and may output scan data to the outside of the integrated circuit 81, such as to the automatic test equipment 82, in the scan mode. As described above with reference to the drawings, the scan flipflops and function flipflops may be included in the scan chain and may latch scan data in the scan mode. In addition, in normal mode, the scan flipflops may latch repair data provided by the built-in self-repair circuit BISR and the function flipflops may latch data required to perform a designed function (namely functional data), which is self-testing, of the built-in self-test circuit BIST. In some implementations, scan flipflops included in the built-in self-test circuit BIST may be automatically inserted to test the automatic test equipment 82. An example of inserting the scan flipflops will be described later with reference to FIG. 13.

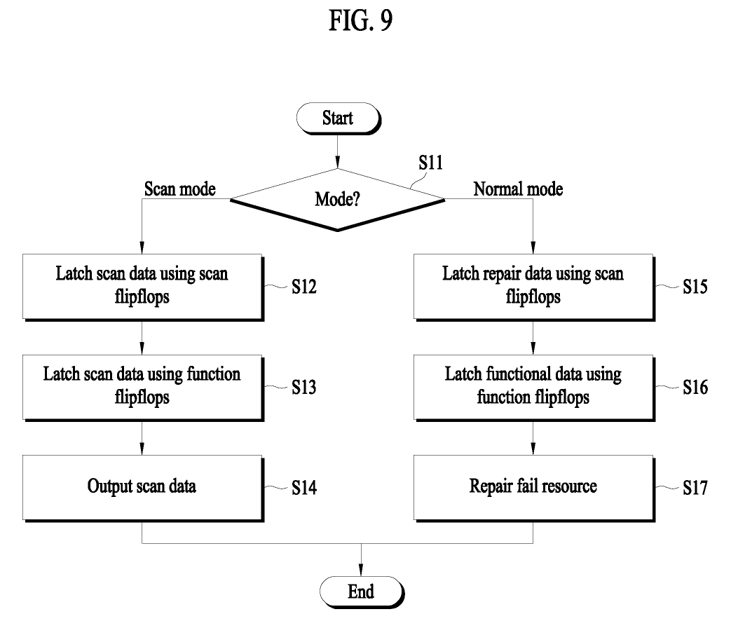

FIG. 9 is a flowchart illustrating an example of a method of built-in self-repair. As illustrated in FIG. 9, the method of built-in self-repair may include operations S11 to S17. In some implementations, the method shown in FIG. 9 may be executed by the integrated circuit 10 of FIG. 1. Hereinafter, FIG. 9 will be described with reference to FIG. 1.

Referring to FIG. 9, a mode may be identified in operation S11. For example, the function block 11 may identify one of the scan mode and normal mode based on a signal received from the outside of the integrated circuit 10. As illustrated in FIG. 9, when the scan mode is identified, operations S12 to S14 may be performed, and operations S15 to S17 may be performed when the normal mode is identified.

When scan mode is identified, scan data may be latched by the scan flipflops SF in operation S12 and by function flipflops FF in operation S13. As described above with reference to the drawings, in scan mode, the scan flipflops SF and function flipflops FF may be included in the scan chain and may latch scan data. Operations S12 and S13 may be executed in an order different from that shown in FIG. 9, and may also be executed in parallel.

In operation S14, the scan data may be output. For example, the scan data latched in operations S12 and S13 may be transmitted through the scan chain and output to the outside of the integrated circuit 10. The scan data may be used to check status of the integrated circuit 10 or to debug the integrated circuit 10.

When normal mode is identified, repair data REP may be latched by the scan flipflops SF in operation S15 and functional data may be latched by the function flipflops FF in operation S16. The scan flipflops inserted to observe the integrated circuit 10 may be unused in the normal mode but be reused to latch the repair data REP instead. As a result, a cost of the built-in self-repair may be reduced. Operations S15 and S16 may be executed in an order different from that shown in FIG. 9, and may also be executed in parallel.

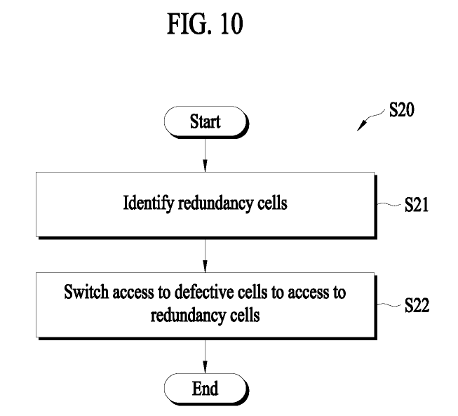

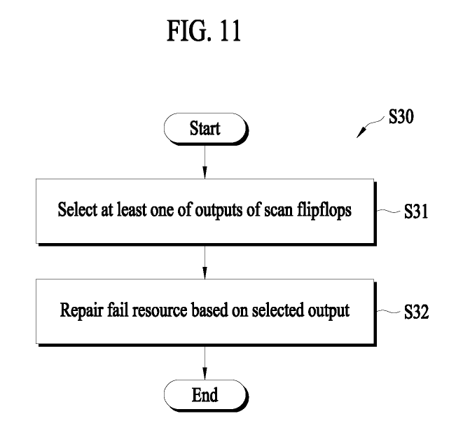

In operation S17, a fail resource may be repaired. For example, the repair data REP latched in operation S15 may be held by the scan flipflops SF. The control circuit 14 may receive the repair data REP from the scan flipflops SF and repair a defective resource among the hardware resources by identifying a defective resource and/or a redundancy resource based on the repair data REP. Examples of operation S17 will be described later with reference to FIGS. 10 and 11.

FIG. 10 is a flowchart illustrating an example of a method of built-in self-repair. For example, the flowchart of FIG. 10 illustrates an example of operation S17 of FIG. 9. As described above with reference to FIG. 9, a defective resource may be repaired in operation S20 of FIG. 10. As illustrated in FIG. 10, operation S20 may include operations S21 and S22. In some implementations, operation S20 may be executed by the integrated circuit 40 of FIG. 4. Hereinafter, FIG. 10 will be described with reference to FIG. 4.

Referring to FIG. 10, redundancy cells may be identified in operation S21. For example, the control circuit 44 may receive repair data REP and identify redundancy cells included in the memory cell array 41 from the repair data REP. In some implementations, the memory cell array 41 may include redundancy columns, and the control circuit 44 may identify at least one of the redundancy columns based on the repair data REP.

In operation S22, an access to defective cells may be switched to an access to redundancy cells. For example, the control circuit 44 may receive an address ADD to access the memory cell array 41 and may identify an access to a defective cell based on the address ADD. When an access to the defective cell is identified, the control circuit 44 may switch the access to the defective cell into an access to the redundancy cells identified in operation S21. Accordingly, the defective cell may be repaired by being replaced with the redundancy cell.

FIG. 11 is a flowchart illustrating an example of a method of built-in self-repair. For example, the flowchart of FIG. 11 illustrates an example of operation S17 of FIG. 9. As described above with reference to FIG. 9, a defective resource may be repaired in S30 of FIG. 11. As illustrated in FIG. 11, operation S30 may include operations S31 and S32. In some implementations, operation S30 may be executed by the integrated circuit 60 of FIG. 6. Hereinafter, FIG. 11 will be described with reference to FIG. 6.

Referring to FIG. 11, at least one of outputs of the scan flipflops may be selected in operation S31. For example, the multiplexing circuit 62 may select one of two signals based on one of bits of the repair data REP provided by the scan flipflops of the function block 61 and provide the selected signal to the control circuit 63. For this, as described above with reference to FIGS. 7A through 7C, the multiplexing circuit 62 may include multiplexers, and a multiplexer may output a signal based on a cell repair enable, which is a bit indicating whether the cell needs to be repaired.

In operation S32, a fail resource may be repaired based on the selected output. For example, the output selected by the multiplexing circuit 62 in operation S31 may be provided to the control circuit 63. The control circuit 63 may identify a defective cell and/or a redundancy cell based on the signal provided by the multiplexing circuit 62 and repair the defective cell.

FIG. 12 is a flowchart illustrating an example of a method of manufacturing an integrated circuit IC. More specifically, the flowchart of FIG. 12 illustrates an example method of manufacturing an integrated circuit IC including cells. As illustrated in FIG. 12, the method of manufacturing an integrated circuit IC may include operations S41, S42, S43, and S44.

A cell library (or a standard cell library) D12 may include information on standard cells, such as, information on functions, characteristics, and layouts. An integrated circuit IC may include a plurality of standards cells. A standard cell is a unit of a layout included in the integrated circuit IC and may be designed to perform a predefined function. The integrated circuit IC may include various types of standard cells and may be arranged and placed along a plurality of rows. In some implementations, the cell library D12 may define the flipflop 20, which has been described above with reference to FIG. 2, as the standard cell. Design rules D14 may include requirements with which a layout of an integrated circuit IC shall comply. For example, the design rules D14 may include requirements such as spacing between patterns on the same layer, minimum width of a pattern, and routing direction of a wiring layer.

In operation S41, a logic synthesis operation of generating netlist data D13 from RTL data D11 may be performed. For example, a semiconductor design tool (e.g., a logic synthesis tool) may generate the netlist data D13 including a bitstream or a netlist by performing logic synthesis from the RTL data D11 written in a hardware description language (HDL), such as the VHSIC hardware description language (VHDL) and Verilog, while referring to the cell library D12. The netlist data D13 may correspond to an input of placement and routing which will be described later. In some implementations, as will be described below with reference to FIG. 13, an operation of adding scan flipflops may be performed in operation S41. Herein, the RTL data D11 may be referred to as input data, and the netlist data D13 that also defines scan flipflops may be referred to as output data.

In operation S42, cells may be placed and pins may be routed. For example, a semiconductor design tool (e.g., a P&R tool) may place cells used in the netlist data D13 by referring to the cell library D12 and the design rules D14. For example, the semiconductor design tool may place cells corresponding to the scan flipflops and function flipflops. Pins of the placed cells may be routed. For example, the semiconductor design tool may generate interconnections that electrically connect output and input pins of the placed cells. The interconnection may include a via of a via layer and/or a pattern of a wiring layer. The semiconductor design tool may generate layout data D15 defining placed cells and generated interconnections, namely the layout of the integrated circuit IC. The layout data D15 may have a format, such as GDSII, and may include geometric information on the cells and interconnections. The semiconductor design tool may refer to the design rules D14 while routing the pins of the cells.

In operation S43, an operation of fabricating a mask may be performed. For example, optical proximity correction (OPC) for correcting distortions such as refraction of light which is caused by characteristics of light during photolithography process may be applied to the layout data D15. Patterns on the mask may be defined to form patterns disposed on a plurality of layers based on data to which OPC is applied, and at least one mask (or, a photomask) for forming patterns of each of the plurality of layers may be fabricated. In some implementations, the layout of the integrated circuit IC may be modified restrictively in operation S43, and the restrictive modification of the integrated circuit IC may be referred to as design polishing, as a post-processing for optimizing the structure of the integrated circuit IC.

In operation S44, a process of manufacturing the integrated circuit IC may be performed. For example, the integrated circuit IC may be manufactured by patterning the plurality of layers using the at least one mask fabricated in operation S43. A front-end-of-line (FEOL) may include planarizing and cleaning a wafer, forming a trench, forming a well, forming a gate electrode, and forming a source and drain, for example. Individual devices such as transistors, capacitors, and resistors may be formed on a substrate by FEOL. In addition, a back-end-of-line (BEOL) may include siliciding a gate and source and drain region, adding a dielectric, planarizing, forming a hole, adding a metal layer, forming a via, forming a passivation layer, for example. Individual devices such as transistors, capacitors, and resistors may be connected to one another by BEOL. In some implementations, middle-of-line (MOL) may be performed between FEOL and BEOL, and contacts may be formed on the individual devices. Then, the integrated circuit IC may be packaged into a semiconductor package, and may be used as a component of different applications.

FIG. 13 is a flowchart illustrating an example of a method of built-in self-repair. For example, the flowchart of FIG. 13 illustrates an example of operation S41 of FIG. 12. As described above with reference to FIG. 12, input data defining the integrated circuit IC as well as output data further defining components for built-in self-repair may be generated in operation S50. As illustrated in FIG. 13, operation S50 may include operations S51 to S55. Hereinafter, FIG. 13 will be described with reference to FIG. 12.

Referring to FIG. 13, input data defining hardware resources may be obtained in operation S51. For example, the semiconductor design tool may obtain the RTL data 111 defining the integrated circuit that executes a designed function. The RTL data D11 may define hardware resources included in the integrated circuit and functional flipflops included in the function block of the integrated circuit.

In operation S52, scan flipflops may be defined. For example, the semiconductor design tool may further define scan flipflops for observing the integrated circuit based on the input data obtained in operation S51. The semiconductor design tool may add information defining the scan flipflops to the input data and the scan flipflops may be added in the integrated circuit defined by the input data as a result. As described above with reference to the drawings, the scan flipflops may be included in the scan chain along with the function flipflops in the scan mode and may latch repair data, unlike the function flipflops latching functional data, in the normal mode.

In operation S53, a repair circuit may be defined. For example, the semiconductor design tool may further define a repair circuit based on the scan flipflops defined in operation S52. The semiconductor design tool may add information defining the repair circuit to the input data and the repair circuit may be added to the integrated circuit defined by the input data as a result. As described above with reference to the drawings, the repair circuit may provide repair data to the scan flipflops added in operation S52 in the normal mode.

In operation S54, a control circuit may be defined. For example, the semiconductor design tool may further define a control circuit based on the scan flipflops defined in operation S52. The semiconductor design tool may add information defining the control circuit to the input data and the control circuit may be added in the integrated circuit defined by the input data as a result. As described above with reference to the drawings, the control circuit may receive repair data from the scan flipflops added in operation S52 and repair the hardware resources based on the repair data in the normal mode.

In operation S55, output data may be generated. For example, the semiconductor design tool may generate output data, such as the netlist data D13 of FIG. 12, that include information further defining the scan flipflops in operation S52, the repair circuit in operation S53, and the control circuit in operation S54 in addition.

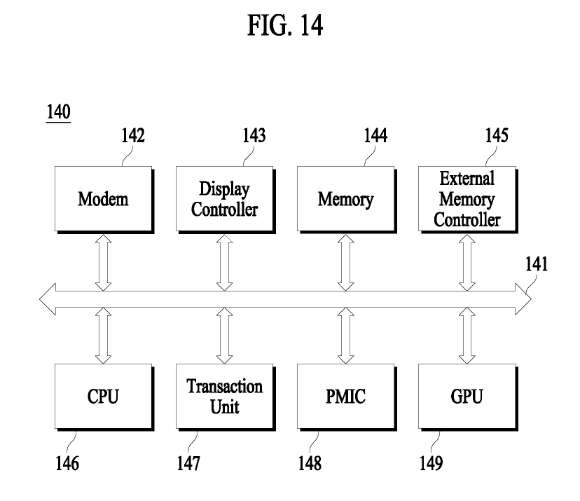

FIG. 14 is a block diagram illustrating an example of a system-on-chip (SoC) 140. The system-on-chip 140 is a semiconductor device which may include the integrated circuit. The system-on-chip 140, which is an integrated circuit with complex blocks, such as intellectual property (IP) that performs different functions, implemented onto a single chip, may include the integrated circuit according to the example implementations of the present disclosure, and provide built-in self-repair which allows to repair hardware resources at reduced cost. Accordingly, the system-on-chip 140 may have high yield, reliability, and efficiency. Referring to FIG. 14, the system-on-chip 140 may include a modem 142, a display controller 143, a memory 144, an external memory controller 145, a central processing unit (CPU) 146, a transaction unit 147, a power management integrated circuit (PMIC) 148, and a graphic processing unit (GPU) 149, and each function block of the system-on-chip 140 may communicate with each other through a system bus 141.

The CPU 146 which is capable of controlling operations of the system-on-chip 140 at the top-level may control operations of other function blocks 142 to 149. The modem 142 may demodulate a signal received from the outside of the system-on-chip 140 or modulate a signal generated within the system-on-chip 140. The external memory controller 145 may control an operation of receiving and transmitting data from and to an external memory device connected to the system-on-chip 140. For example, a program and/or data stored in the external memory device may be transmitted to the CPU 146 or GPU 149 under the control of the external memory controller 145. The GPU 149 may execute program instructions related to graphic processing. The GPU 149 may receive graphic data through the external memory controller 145 and may transmit processed graphic data to the outside of the system-on-chip 140 through the external memory controller 145. The transaction unit 147 may monitor data transactions of each function block and the PMIC 148 may control the power supplied to each function block under the control of the transaction unit 147. The display controller 143 transmit the data generated within the system-on-chip 140 to a display by controlling the display (or a display device) outside the system-on-chip 140. The memory 144 may include non-volatile memory such as electrically erasable programmable read-only memory (EEPROM) and flash memory, and may include volatile memory such as dynamic random-access memory (DRAM) and static random-access memory (SRAM).

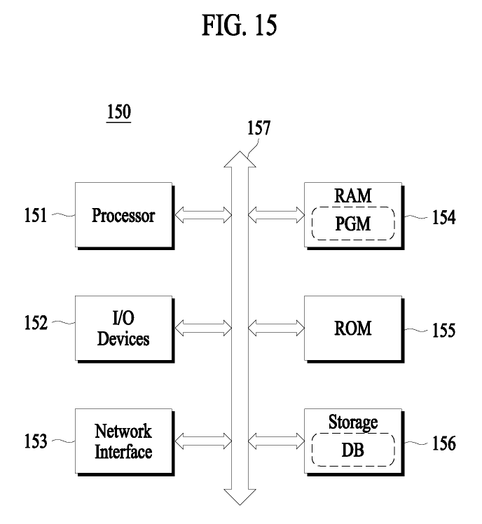

FIG. 15 is a block diagram illustrating an example of a computing system 150 including a memory for storing a program. The method of built-in self-repair according to the example implementations of the present disclosure, such as at least one of operations shown in FIGS. 12 and 13, may be executed by the computing system (or a computer) 150.

The computing system 150 may be a fixed type of computing system, such as a desktop computer, workstation, and server, or a portable computing system, such as a laptop computer. As illustrated in FIG. 15, the computing system 150 may include a processor 151, input/output devices 152, a network interface 153, a random-access memory 154, a read-only memory 155, and a storage 156. The processor 151, the input/output devices 152, the network interface 153, the RAM 154, the ROM 155, and the storage 156 may be connected to a bus 157, and may communicate with each other through the bus 157.

The processor 151 may be referred to as a processing unit, and may include at least one core for executing any instruction set (e.g., Intel-Architecture-32 (IA-32), 64-bit extension IA-32, x86-64, PowerPC, Sparc, MIPS, ARM, IA-64, etc.), such as a micro-processor, an application processor (AP), a digital signal processor (DSP), and a graphic processing unit (GPU). For example, the processor 151 may access memory, that is, RAM 154 or ROM 155, through the bus 157 and execute instructions stored in the RAM 154 or ROM 155.

The RAM 154 may store a program PGM for the method according to the example implementations of the present disclosure or at least a portion thereof, and the program PGM may allow the processor 151 to execute a method, such as at least one of the operations included in the methods shown in FIGS. 12 and 13. That is, the program PGM may include a number of instructions executable by the processor 151, and the instructions included in the program PGM may allow the processor 151 to execute at least one of the operations included in the flowcharts described above.

The storage 156 may not lose data stored even when the power supplied to the computing system 150 is cut. For example, the storage 156 may include a non-volatile memory device or a storage medium such as a magnetic tape, optical disc, and magnetic disc. In addition, the storage 156 may be detachable from the computing system 150. The storage 156 may store the program PGM, and the program PGM or at least a part of the program PGM may be loaded to the RAM 154 from the storage 156 before the program PGM is executed by the processor 151. Alternatively, the storage 156 may store a file written in a programming language, and the program PGM generated from the file via compiler, for example, or at least a part thereof may be loaded to the RAM 154. In addition, as illustrated in FIG. 15, the storage 156 may store a database DB, and the database DB may include information required for designing the integrated circuit, such as data defining the integrated circuit, the cell library D12 of FIG. 12, and/or the design rules D14.

The storage 156 may store data to be processed by the processor 151 or data processed by the processor 151. That is, the processor 151 may generate data by processing data stored in the storage 156 according to the program PGM and may store the generated data to the storage 156. For example, the storage 156 may store the RTL data D11, the netlist data D13, and/or the layout data D15 of FIG. 12.

The input/output devices 152 may include an input device, such as a keyboard and a pointing device, and may also include an output device, such as a display device and a printer. For example, a user may trigger execution of the program PGM by the processor 151 using the input/output devices 152, input the RTL data D11 and/or the netlist data D13 of FIG. 12, or check the layout data D15 of FIG. 12.

The network interface 153 may provide an access to a network outside the computing system 150. For example, the network may include a number of computing systems and communication links, and the communication links may include wired links, optical links, wireless links, or any other types of links.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features can in some cases be excised from the combination, and the combination may be directed to a subcombination or variation of a subcombination.

As described above, example implementations have been disclosed in the drawings and specification. While the example implementations have been described with reference to specific terms, it shall be understood that the terms used herein are only for the purpose of describing the technical spirit of the present disclosure and not for limiting the scope of the present disclosure as defined in the claims. Therefore, those skilled in the art will appreciate that various modifications and equivalent implementations are possible without departing from the scope of the present disclosure.

What is claimed is:

1. An integrated circuit comprising a plurality of hardware resources, the integrated circuit comprising:
at least one first flipflop configured to latch scan data in a first mode and to latch repair data in a second mode, the scan data being output from the integrated circuit; and
a control circuit configured to repair a defective resource among the plurality of hardware resources based on the repair data latched by the at least one first flipflop in the second mode.

2. The integrated circuit of claim 1, comprising at least one second flipflop configured to latch the scan data in the first mode and to latch functional data in the second mode.

3. The integrated circuit of claim 1, comprising a memory cell array including a plurality of cells, the plurality of hardware resources including the plurality of cells, and
wherein the control circuit is configured to identify at least one redundancy cell among the plurality of cells based on the repair data and switch an access to at least one defective cell among the plurality of cells to an access to the at least one redundancy cell.

4. The integrated circuit of claim 3, wherein the at least one redundancy cell corresponds to at least one column in the memory cell array.

5. The integrated circuit of claim 3, wherein the repair data includes:
a first data indicating a necessity of repair; and
a second data indicating an address of the at least one defective cell.

6. The integrated circuit of claim 5, comprising a multiplexing circuit configured to select a portion of outputs of the at least one first flipflop and to provide the portion of outputs to the control circuit based on the first data.

7. The integrated circuit of claim 1, comprising a repair circuit comprising a non-volatile memory, the non-volatile memory being configured to store the repair data and to provide the repair data to the at least one first flipflop in the second mode.

8. The integrated circuit of claim 1, comprising a test circuit configured to test the plurality of hardware resources in the second mode.

9. A method performed by an integrated circuit comprising a plurality of hardware resources, the method comprising:
latching scan data by at least one first flipflop in a first mode, the scan data being output from the integrated circuit;
latching repair data by the at least one first flipflop in a second mode; and
repairing a defective resource, among the plurality of hardware resources, based on the repair data latched in the at least one first flipflop in the second mode.

10. The method of claim 9, comprising:
latching the scan data by at least one second flipflop in the first mode; and
latching functional data by the at least one second flipflop in the second mode.

11. The method of claim 9, wherein the integrated circuit comprises a memory cell array including a plurality of cells, the plurality of hardware resources including the plurality of cells, and
wherein repairing the defective resource in the second mode comprises:
identifying at least one redundancy cell among the plurality of cells based on the repair data; and
switching an access to at least one defective cell among the plurality of cells to an access to the at least one redundancy cell.

12. The method of claim 11, wherein the at least one redundancy cell corresponds to at least one column in the memory cell array.

13. The method of claim 11, wherein the repair data includes:
a first data indicating a necessity of repair; and
a second data indicating an address of the at least one defective cell.

14. The method of claim 13, wherein repairing the defective resource comprises:
selecting a portion of outputs of the at least one first flipflop based on the first data; and
repairing the defective resource based on the selected portion of outputs.

15. The method of claim 9, comprising:
reading, in the second mode, the repair data from a non-volatile memory, wherein the non-volatile memory is included in the integrated circuit and is configured to store the repair data; and
providing the repair data to the at least one first flipflop.

16. The method of claim 9, comprising testing the plurality of hardware resources in the second mode.

17. A method performed by at least one processor for an integrated circuit providing built-in self-repair, the method comprising:
obtaining input data, the input data defining a plurality of hardware resources included in the integrated circuit; and
generating output data based on the input data, the output data defining the integrated circuit,
wherein generating the output data comprises:
adding information defining at least one first flipflop to the input data, the at least one first flipflop being configured to latch scan data in a first mode and to latch repair data in a second mode;
adding information defining a repair circuit to the input data, the repair circuit being configured to provide the repair data to the at least one first flipflop in the second mode; and
adding information defining a control circuit to the input data, the control circuit being configured to repair a defective resource among the plurality of hardware resources based on the repair data latched by the at least one first flipflop.

18. The method of claim 17, wherein the input data defines at least one second flipflop, the at least one second flipflop being configured to latch the scan data in the first mode and to latch functional data in the second mode.

19. The method of claim 17, wherein the input data defines a memory cell array including a plurality of cells, the plurality of hardware resources including the plurality of cells, and
wherein the control circuit is configured to identify at least one redundancy cell among the plurality of cells based on the repair data and switch an access to at least one defective cell among the plurality of cells to an access to the at least one redundancy cell.

20. The method of claim 19, wherein the at least one redundancy cell corresponds to at least one column in the memory cell array.
